(19) United States
(12) Patent Application Publication
(10) Pub. No.: US 2023/0140669 A1
(43) Pub. Date: May 4, 2023

(54) PHOTOSENSITIVE STRUCTURAL BODY AND METHOD OF PRODUCING THE PHOTOSENSITIVE STRUCTURAL BODY, AND INKJET RECORDING HEAD

(71) Applicant: CANON KABUSHIKI KAISHA, Tokyo (JP)

(72) Inventors: Hikaru Sugimoto, Kanagawa (JP); Kazunari Ishizuka, Shizuoka (JP); Satoshi Tsutsui, Kanagawa (JP); Yohei Hamade, Tokyo (JP); Miho Ishii, Kanagawa (JP); Haruka Yamaji, Tokyo (JP)

(21) Appl. No.: 17/935,185

(22) Filed: Sep. 26, 2022

(30) Foreign Application Priority Data
Oct. 28, 2021 (JP) 2021-176468

(51) Int. Cl. G03F 7/00; B41J 2/16; G03F 7/038

(52) U.S. Cl. CPC G03F 7/0015; B41J 2/1631; B41J 2/164; G03F 7/0382

(57) ABSTRACT

Provided is a photosensitive structural body including: a substrate having a hydroxy group on a first surface thereof; and a cured product of a negative photosensitive resin composition arranged on the substrate, wherein the negative photosensitive resin composition contains an epoxy compound (A), a photobase generator (B), and an aromatic compound (C), and the aromatic compound (C) is a compound represented by the following general formula (1):

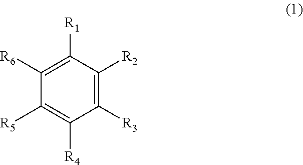

in the general formula (1), four of R₁ to R₆ each independently represent a hydrogen atom or an alkyl group, and remaining two thereof each independently represent a functional group selected from an unsubstituted amino group (—NH₂), a hydroxy group (—OH), and a carboxyl group (—COOH), provided that the two functional groups each selected from an unsubstituted amino group, a hydroxy group, and a carboxyl group are functional groups different from each other.

### BACKGROUND OF THE INVENTION

### Field of the Invention

The present disclosure relates to a photosensitive structural body and a method of producing the photosensitive structural body, and to an inkjet recording head using the photosensitive structural body.

### Description of the Related Art

In recent years, a photolithography technology, which includes applying a negative photosensitive resin composition onto a substrate, exposing the composition through a mask having a predetermined pattern, and then removing an unexposed portion to produce a structural body having a target shape, has been attracting attention in industrial fields, such as a semiconductor and printing. An improvement in adhesiveness between the substrate and the negative photosensitive resin composition can impart, to the structural body, durability against a liquid component and an external force such as rubbing, and hence high adhesiveness between the substrate and the negative photosensitive resin composition is required. In particular, when the structural body is applied to a recording head to be used in an inkjet printer, the improvement of the adhesiveness can suppress the resin from peeling from the substrate at the time of the wiping of the surface of the head. As a result, an increase in number of times that the recording head can be used, and the enlargement of a degree of freedom in selection of an ink because of, for example, the ability of the head to correspond to various inks are expected.

Various methods have been known as methods of improving the adhesiveness between the substrate and the negative photosensitive resin composition. Of those, there has been generally used a method including improving the reactivity of the resin with a photoacid generator to strengthen a bond between the negative photosensitive resin composition and the substrate, to thereby improve the adhesiveness. However, in photocationic polymerization including using the photoacid generator, an acid remains after the production of the structural body, and hence the modification or corrosion of the substrate or the resin resulting from a basic liquid typified by an ink (its pH is often adjusted to from 7 to 11 for the dissolution stability of its coloring material) has become a problem in some cases. In view of the foregoing, in Japanese Patent Application Laid-Open No. 2006-341442, a structural body is produced by performing photocationic polymerization through use of a photobase generator instead of the photoacid generator. Thus, there is obtained a structural body that is more hardly dissolved in or modified by a basic liquid than the related-art structural body is.

### SUMMARY OF THE INVENTION

Meanwhile, conventional anionic polymerization involves the following problems. First, it has been known that the reaction rate of the anionic polymerization is slow, and hence a reaction for forming the bond between the negative photosensitive resin composition and the substrate hardly advances, with the result that the bond therebetween weakens. Accordingly, there is a problem in that the cured product of the resin composition peels from the substrate at the time of its liquid contact. In the case of, for example, a flow path forming member in an inkjet head, the phrase “at the time of the liquid contact” means a timing after the member has been filled with an ink and has been exposed thereto for a certain time period. Meanwhile, a method including adding a base-proliferating agent that is decomposed by the action of a base to generate another base has been known as a method of increasing the reaction rate to strengthen the above-mentioned bond. However, as the addition amount of the base-proliferating agent increases, there has occurred a problem in that the sensitivity of the negative photosensitive resin composition to light rises to reduce pattern shape reproducibility at the time of its exposure.

An object of the present disclosure is to provide a structural body, which can achieve both of adhesiveness between its substrate and negative photosensitive resin composition, and pattern shape reproducibility while suppressing a rise in sensitivity of the negative photosensitive resin composition to light (hereinafter also referred to as “photosensitive structural body”), and an inkjet recording head using the photosensitive structural body.

According to one aspect of the present disclosure, there is provided a photosensitive structural body including: a substrate having a hydroxy group on a first surface thereof; and a cured product of a negative photosensitive resin composition arranged on the substrate, wherein the negative photosensitive resin composition contains an epoxy compound (A), a photobase generator (B), and an aromatic compound (C), and the aromatic compound (C) is a compound represented by the following general formula (1):

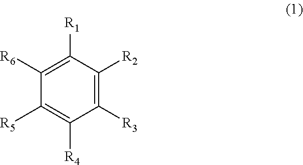

in the general formula (1), four of R₁ to R₆ each independently represent a hydrogen atom or an alkyl group, and remaining two thereof each independently represent a functional group selected from an unsubstituted amino group (—NH₂), a hydroxy group (—OH), and a carboxyl group (—COOH), provided that the two functional groups each selected from an unsubstituted amino group, a hydroxy group, and a carboxyl group are functional groups different from each other.

Further features of the present invention will become apparent from the following description of exemplary embodiments with reference to the attached drawings.

### BRIEF DESCRIPTION OF THE DRAWINGS

FIG. 1 is a view for illustrating an example of the manner in which an aromatic compound (C) forms a crosslinked structure between a substrate and an epoxy compound.

FIG. 2A is a schematic view of the substrate and an ink flow path mold.

FIG. 2B is a schematic view after the formation of a resin layer on the substrate.

FIG. 2C is a schematic view during pattern exposure through photomasks.

FIG. 2D is a schematic view after the formation of ejection orifices by development.

FIG. 2E is a view for illustrating the formation of an ink supply orifice.

FIG. 2F is a schematic view after the formation of a flow path.

FIG. 3A is a schematic view for illustrating the formation of a negative photosensitive resin on a substrate.

FIG. 3B is a schematic view for illustrating the measurement of adhesiveness through the pressing of the negative photosensitive resin on the substrate with a tool.

### DESCRIPTION OF THE EMBODIMENTS

A photosensitive structural body according to the present disclosure includes a substrate and a cured product of a negative photosensitive resin composition arranged on the substrate. In addition, the structural body is characterized in that a hydroxy group is present on the first surface of the substrate, that the negative photosensitive resin composition contains an epoxy compound (A), a photobase generator (B), and an aromatic compound (C), and that the aromatic compound (C) has a structure represented by the general formula (1). When a substrate having a hydroxy group is used as the substrate, and the negative photosensitive resin composition contains the aromatic compound (C) represented by the general formula (1), an increase in amount of a base to be generated in the resin composition can be suppressed. In addition, an unsubstituted amino group, a hydroxy group, or a carboxyl group in the aromatic compound (C) forms a hydrogen bond with the hydroxy group of the substrate. Further, those functional groups each have a high affinity for an epoxy group. Accordingly, the aromatic compound (C) reacts with the hydroxy group of the substrate and the epoxy compound (A) to form a crosslinked structure, and hence adhesiveness between the substrate and the negative photosensitive resin composition can be improved.

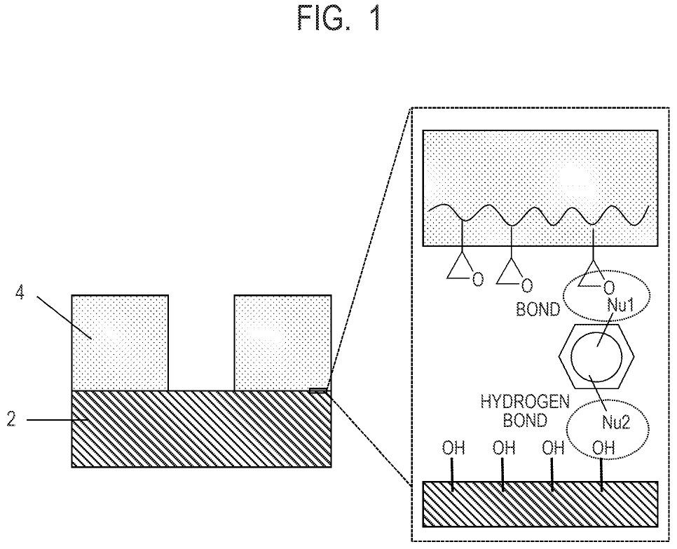

Thus, the adhesiveness between the substrate and the negative photosensitive resin composition was able to be improved while the sensitivity of the negative photosensitive resin composition to light was maintained. An example of the manner in which the aromatic compound (C) forms the crosslinked structure between the hydroxy group of the substrate and the epoxy compound is illustrated in FIG. 1.

Next, an embodiment according to the present disclosure is described in detail.

### Photosensitive Structural Body

### Substrate

The substrate applicable to the production of the photosensitive structural body according to the present disclosure has a hydroxy group at least on its first surface. The first surface of the sub state means the surface of the substrate on the side on which the negative photosensitive resin composition according to the present disclosure is arranged. For example, a substrate obtained by introducing a hydroxy group into a silicon substrate is generally used as the substrate having a hydroxy group. A method of introducing a hydroxy group into a substrate is, for example, plasma treatment. In general, plasma is an ionized gas state, and is formed of active species in various states, such as an ion, an electron, and a radical. The plasma treatment can activate the surface of the silicon substrate to impart a reactive active group to the surface. The plasma treatment is, for example, reduced-pressure plasma treatment described in Japanese Patent Application Laid-Open No. 2012-126107. In the reduced-pressure plasma treatment, the surface of the substrate is preferably subjected to hydrophilic treatment with the mixed gas of a non-reactive gas such as an argon gas and an oxygen gas. In addition, the mixing ratio of the oxygen gas in the mixed gas is preferably from 10% to 25%.

### Negative Photosensitive Resin Composition

### Epoxy Compound (A)

An epoxy resin having at least two or more epoxy groups in a molecule thereof is used as the epoxy compound (A). Examples thereof include, but not limited to, a reaction product between bisphenol A and epichlorohydrin, a reaction product between bromo-containing bisphenol A and epichlorohydrin, a reaction product between phenol novolac or o-cresol novolac and epichlorohydrin, and a polyfunctional epoxy resin having an oxycyclohexane skeleton.

In addition, an epoxy compound that is solid at normal temperature is preferably used because the diffusion of a polymerization active species generated by photoirradiation into the epoxy resin is suppressed, and hence excellent patterning accuracy and an excellent shape can be obtained.

In addition, the epoxy equivalent of the epoxy compound is preferably 1,000 or less. When the epoxy equivalent is 1,000 or less, a reduction in crosslinking density at the time of the curing reaction of the negative photosensitive resin composition is suppressed, and hence reductions in adhesiveness and liquid resistance of the photosensitive structural body can be prevented.

### Photobase Generator (B)

Any substance may be used as the photobase generator (B) without any particular limitation as long as the substance generates a base when irradiated with light. Specific examples thereof include carboxylic acid ammonium salts, α-aminoacetophenone derivatives, TPS-OH, NBC-101, and ANC-101 (product names) manufactured by Midori Kagaku Co., Ltd., N-(2-nitrobenzyloxycarbonyl)imidazole, N-(3-nitrobenzyloxycarbonyl)imidazole, and N-(4-nitrobenzyloxycarbonyl)imidazole.

The addition amount of the photobase generator (B) is not particularly limited as long as the amount enables the curing of the epoxy compound (A). Specifically, the addition amount of the photobase generator (B) may be set to 3 mass% or more with respect to the epoxy compound (A).

In addition, a base-proliferating agent (D) may be added as a compound that complements the role of the photobase generator (B) to the negative photosensitive resin composition as long as its amount is small. Any substance may be used as the base-proliferating agent (D) without any particular limitation as long as the substance is decomposed by the action of a base to generate a basic substance. Specific examples thereof may include urethane compounds described in Japanese Patent Application Laid-Open No. 2000-330270. Each of the urethane compounds may have two or more urethane bonds. Of the urethane compounds described in Japanese Patent Application Laid-Open No. 2000-330270, a urethane compound represented by the following general formula (2) or (3) is preferably used.

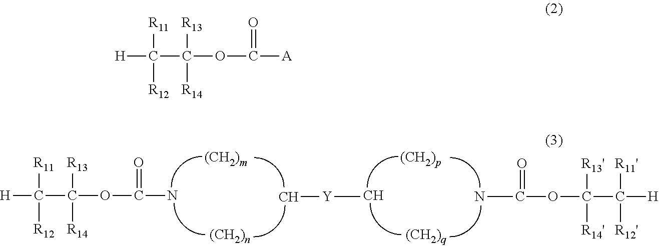

In the general formula (2), R₁₁ and R₁₂ each independently represent a hydrogen atom, a substituent, or an electron-withdrawing group, but at least one thereof represents an electron-withdrawing group, and R₁₃ and R₁₄ each independently represent a hydrogen atom or a substituent. Examples of the substituent include: an alkyl group having 1 to 12 carbon atoms, preferably 1 to 6 carbon atoms; a cycloalkyl group having 5 to 10 carbon atoms, preferably 6 to 8 carbon atoms; an aryl group having 6 to 14 carbon atoms, preferably 6 to 10 carbon atoms; and an arylalkyl group having 7 to 15 carbon atoms, preferably 7 to 11 carbon atoms. In addition, examples of the electron-withdrawing group include a fluorenyl group, an organic sulfoxide group, a cyano group, a nitro group, an ester group, a carbonyl group, an amide group, and a pyridyl group. R₁₁ and R₁₂ may be bonded to each other to form a ring, and for example, R₁₁ and R₁₂ may form a fluorenyl group. A represents an unsubstituted amino group, a monosubstituted amino group, or a disubstituted amino group, and in the disubstituted amino group, two substituents may be bonded to each other to form a nitrogen-containing ring. A substituent of the amino group is, for example, an organic group, such as an alkyl group, cycloalkyl group, aryl group, or arylalkyl group having 1 to 18 carbon atoms.

In the general formula (3), R₁₁ to R₁₄ have the same meanings as those of R₁₁ to R₁₄ in the general formula (2). R₁₁′ and R₁₂′ each independently represent a hydrogen atom, a substituent, or an electron-withdrawing group, but at least one thereof represents an electron-withdrawing group, and R₁₃′ and R₁₄′ each independently represent a hydrogen atom or a substituent. Examples of the substituent and the electron-withdrawing group may include the same groups as those exemplified in the general formula (2). R₁₁′ and R₁₂′ may be bonded to each other to form a ring, and for example, R₁₁′ and R₁₂′ may form a fluorenyl group. Y represents an alkylene group having 1 to 8 carbon atoms, preferably 2 to 6 carbon atoms. “m” and “n” each independently represent a number of from 1 to 6, preferably from 2 to 4, and m+n is from 4 to 12, preferably from 4 to 8. “p” and “q” each independently represent a number of from 1 to 6, preferably from 2 to 4, and p+q is from 4 to 12, preferably from 4 to 8.

The urethane compound represented by the general formula (2) or (3) may be synthesized by a method described in Japanese Patent Application Laid-Open No. 2000-330270.

When the negative photosensitive resin composition contains the base-proliferating agent (D), its content is preferably 1 mol or less with respect to 1 mol of the photobase generator (B). As described above, the base-proliferating agent (D) accelerates a rise in sensitivity of the negative photosensitive resin composition. However, when the addition amount of the base-proliferating agent (D) with respect to 1 mol of the photobase generator (B) is 1 mol or less, a reduction in pattern shape reproducibility of the photosensitive structural body can be suppressed.

### Aromatic Compound (C)

The aromatic compound (C) is a compound that can react with the hydroxy group of the substrate and the epoxy compound (A) to form a crosslinked structure, and specifically, the compound has a structure represented by the following general formula (1).

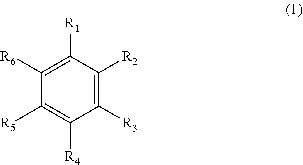

The reason why a benzene-type aromatic compound was selected as an additive to be incorporated into the negative photosensitive resin composition is as described below.

First, when a linear compound and an aromatic compound are compared to each other, the latter is preferred because the latter has stiffness and hence improves the crosslinking strength of the crosslinked structure. In addition, examples of the aromatic compound generally include benzene-type, naphthalene-type, and anthracene-type compounds. However, when a naphthalene structure or an anthracene structure is irradiated with light, such structure causes triplet energy transfer to enter a triplet state, and hence starts to show a sensitizing action. As a result, the sensitivity of the negative photosensitive resin composition rises. Accordingly, the naphthalene- or anthracene-type compound is unsuitable as the additive to be used in the present disclosure. In view of the foregoing, the benzene-type aromatic compound is suitable as the additive to be incorporated into the negative photosensitive resin composition.

Four of R₁ to R₆ in the general formula (1) each independently represent a hydrogen atom or an alkyl group, and the remaining two thereof each independently represent a functional group selected from an unsubstituted amino group (—NH₂), a hydroxy group (—OH), and a carboxyl group (—COOH), provided that the two functional groups each selected from an unsubstituted amino group, a hydroxy group, and a carboxyl group are functional groups different from each other. Although the number of the carbon atoms of the alkyl group is not particularly limited, the number is preferably as small as possible. Specifically, an alkyl group having 1 to 3 carbon atoms is preferred. In addition, the two functional groups each selected from an unsubstituted amino group, a hydroxy group, and a carboxyl group are preferably a combination of an unsubstituted amino group and a carboxyl group. The reason for the foregoing is described below.

First, in consideration of reactivity between an epoxy group and the aromatic compound (C), a reaction therebetween is caused by the transfer of an electron onto an oxygen atom for forming the epoxy through the attack of the nucleophilic functional group (Nu) of the aromatic compound (C) on a carbon atom of the epoxy group (the following reaction formula (I)). Accordingly, one of R₁ to R₆ of the aromatic compound (C) preferably represents a functional group having stronger nucleophilicity. An unsubstituted amino group, a hydroxy group, and a carboxyl group are arranged as follows in order of reducing nucleophilicity: unsubstituted amino group>hydroxy group>carboxyl group. Accordingly, an unsubstituted amino group is most preferred as the nucleophilic functional group of the aromatic compound (C).

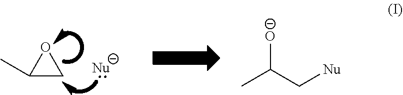

Meanwhile, bonds between hydroxy groups on the substrate and the aromatic compound (C) are mainly hydrogen bonds. A source for the occurrence of a hydrogen bond is electron bias along with polarization in a molecule of the compound, and hence polarization in a functional group thereof is preferably as large as possible. When an unsubstituted amino group, a hydroxy group, and a carboxyl group are compared to each other, the carboxyl group shows the largest polarization, and hence its electrons are easily biased. Accordingly, a hydrogen bond is easily produced. Accordingly, a carboxyl group is desirable as a hydrogen-bonding functional group of the aromatic compound (C).

In view of the foregoing, the aromatic compound (C) preferably has an unsubstituted amino group and a carboxyl group.

Although the substitution positions of the two functional groups each selected from an unsubstituted amino group, a hydroxy group, and a carboxyl group may by any one of ortho, para, and meta arrangements, the para arrangement is preferred.

In addition, the inventors have made extensive investigations, and as a result, have found that the content of the aromatic compound (C) in the negative photosensitive resin composition is preferably 0.065 mol or more and 0.130 mol or less with respect to 1 mol of an epoxy group in the epoxy compound (A). When the content of the aromatic compound (C) with respect to 1 mol of the epoxy group is 0.065 mol or more, a crosslinked structure is sufficiently formed between the hydroxy group of the substrate and the epoxy group, and hence adhesiveness between the substrate and the composition is further improved. In addition, the inventors have investigated an influence of a change in content of the aromatic compound (C) with respect to 1 mol of the epoxy group on the adhesiveness. As a result, the inventors have revealed that when the content of the aromatic compound (C) falls within the range of from 0.078 mol to 0.117 mol, the adhesiveness becomes maximum, and even when the aromatic compound (C) is further added, the adhesiveness does not change. Accordingly, the content of the aromatic compound (C) with respect to 1 mol of the epoxy group in the epoxy compound (A) in the negative photosensitive resin composition is more preferably from 0.078 mol to 0.117 mol. The range is a range corresponding to the range in which the adhesiveness becomes steady at the maximum value±10%.

### Other Component

In addition to the above-mentioned respective components, an additive, such as a silane coupling agent or a plasticity-imparting agent, may be appropriately added to the negative photosensitive resin composition according to the present disclosure as required. The silane coupling agent is added for the purpose of further improving the adhesiveness between the substrate and the negative photosensitive resin composition. In addition, the negative photosensitive resin composition according to the present disclosure may contain a solvent for dissolving the respective components.

### Method of producing Photosensitive Structural Body

The photosensitive structural body according to the present disclosure is obtained by: applying, onto the first surface of the substrate having a hydroxy group on the first surface, the negative photosensitive resin composition containing the above-mentioned respective components to form a coating film of the negative photosensitive resin composition; and curing the coating film. That is, a method of producing the photosensitive structural body according to the present disclosure includes at least the following steps (i) to (iii):

(i) a step of preparing a substrate having a hydroxy group on a first surface thereof;

(ii) a step of applying, onto the first surface of the substrate having a hydroxy group, a negative photosensitive resin composition containing an epoxy compound (A), a photobase generator (B), and an aromatic compound (C) having a structure represented by the general formula (1) to form a coating film; and

(iii) a step of curing the coating film.

Thus, the photosensitive structural body according to the present disclosure including the substrate and the cured product of the negative photosensitive resin composition on the substrate is obtained.

In the step (iii), the coating film of the negative photosensitive resin composition according to the present disclosure is preferably cured by anionic polymerization. In photocationic polymerization including using a photoacid generator, in general, the rate at which an acid is generated is fast and the amount of the acid to be generated is large, and hence the acid is liable to remain after the curing reaction. Accordingly, when the aromatic compound (C) contains an unsubstituted amino group, the acid remaining after the curing reaction reacts with the unsubstituted amino group in the aromatic compound (C) to undergo alteration. Conditions for heating treatment in the anionic polymerization only need to be appropriately set in accordance with, for example, an exposure amount and the kinds of the epoxy compound (A) and the like to be used. The exposure amount may be set to, for example, from 4,000 J/m² to 7,000 J/m². A heating temperature may be set to, for example, from 80° C. to 110° C. In addition, a heating time may be set to, for example, from 3 minutes to 6 minutes.

### Inkjet Recording Head

The photosensitive structural body according to the present disclosure may be used as part of an inkjet recording head. Specifically, the substrate having a hydroxy group on the first surface in the photosensitive structural body according to the present disclosure may be used as a substrate in the inkjet recording head, and the cured product of the negative photosensitive resin composition according to the present disclosure may be used as a flow path forming member in the inkjet recording head.

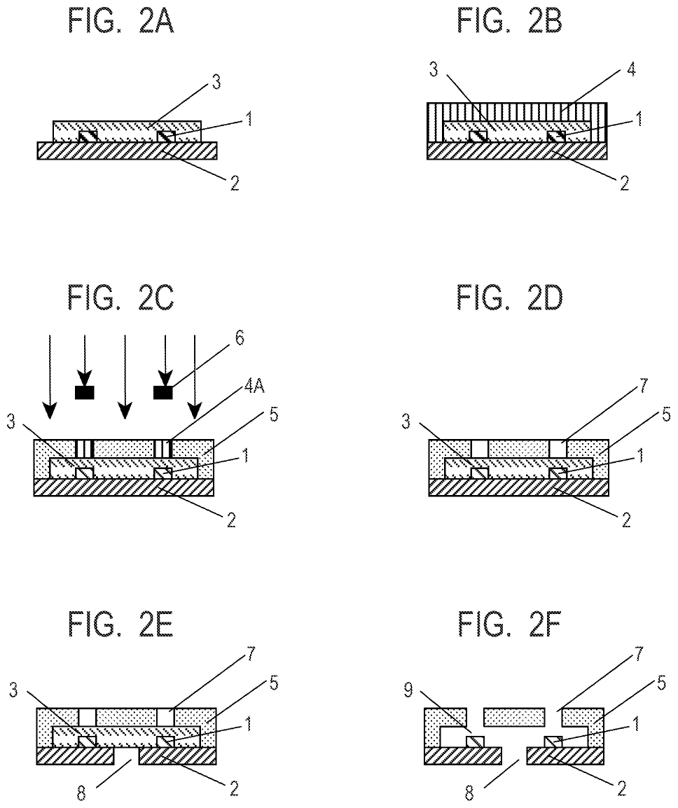

FIG. 2A to FIG. 2F are schematic sectional views for illustrating an example of the production flow of the inkjet recording head according to the present disclosure. As illustrated in FIG. 2A, energy-generating elements 1, such as electrothermal conversion elements or piezoelectric elements, are formed on the first surface (surface having bonded thereto a hydroxy group) of a substrate 2 having a hydroxy group. Glass, ceramic, plastic, a metal, or the like may be used as the substrate. In addition, in general, various functional layers such as a protective layer are arranged for the purpose of improving the tolerance of each of the energy-generating elements. Also in the present disclosure, such functional layer may be arranged. A positive resist is preferably used to form an ink flow path mold 3 on the substrate.

Next, the negative photosensitive resin composition according to the present disclosure is used to form a resin layer 4 on the ink flow path mold 3 (FIG. 2B). At this time, the resin layer 4 may be formed by: dissolving the materials of the composition for forming the resin layer 4 in a solvent to prepare a solution; and applying the solution onto the ink flow path mold 3 by a spin coating method, a roll coating method, or the like. However, the solvent needs to be selected so that the resin for forming the ink flow path mold 3 may not be dissolved. The thickness of the resin layer 4 at the time of the formation of the resin layer 4 through use of the negative photosensitive resin composition may be set to, for example, from 16 μm to 25 μm.

Next, as illustrated in FIG. 2C, pattern exposure is performed through photomasks 6. Light to be used in the pattern exposure may be appropriately selected from, for example, UV light, deep-UV light, an electron beam, and an X-ray in accordance with the photosensitive region of the photobase generator to be used. After the exposure, heating treatment may be appropriately performed. Next, development is performed to remove unexposed portions 4A, to thereby form ejection orifices 7 (FIG. 2D).

Next, a mask (not shown) for producing an ink supply orifice 8 is appropriately arranged on the second surface (surface opposite to the first surface) of the substrate, and the surface of the substrate is protected with a rubber film, followed by the formation of the ink supply orifice 8 by anisotropic etching (FIG. 2E). After that, the rubber film is removed, and UV light is applied to the entire surface of the substrate to decompose and remove the positive resist, to thereby form a flow path 9 (FIG. 2F). Further, heating treatment is performed for completely curing the negative photosensitive resin composition, and then electrical connection and an ink-supplying unit are appropriately arranged to provide the inkjet recording head. In the inkjet recording head illustrated in FIG. 2F, the cured product of the negative photosensitive resin composition according to the present disclosure is used as a flow path forming member 5.

### EXAMPLES

Examples and Comparative Examples are described below, but the present disclosure is not limited thereto. As evaluations, a photosensitive structural body including a silicon substrate having a hydroxy group (except for Comparative Example 3), and a negative photosensitive resin composition according to each of Examples and Comparative Examples was produced, and was evaluated for its pattern shape reproducibility and adhesiveness. Further, an inkjet recording head was produced by using the negative photosensitive resin composition according to each of Examples and Comparative Examples, and was evaluated for peeling resistance between its substrate and negative photosensitive resin composition.

### Example 1

### Hydrophilic Treatment of Silicon Substrate

To introduce a hydroxy group into a silicon substrate, reduced-pressure plasma treatment described in Japanese Patent Application Laid-Open No. 2012-126107 was performed. In the reduced-pressure plasma treatment, the surface of the substrate was subjected to hydrophilic treatment with the mixed gas of an argon gas and an oxygen gas. The ratio of the oxygen gas in the mixed gas was set to 20%. Thus, the silicon substrate having a hydroxy group was produced.

### Preparation of Negative Photosensitive Resin Composition

First, 100 g of EHPE3150 (product name, manufactured by Daicel Chemical Industries, Ltd.) was added as the epoxy compound (A) to 70 g of xylene, and was dissolved therein by stirring the mixture for 3 days. After that, 5 g of SILQUEST A-187 (product name, manufactured by Momentive Performance Materials LLC) serving as a silane coupling agent, 5 g of dimethylammonium α-naphthylglyoxylate serving as the photobase generator (B), 10 g of 4,4′-[bis[[(9-fluorenylmethyl)oxy]carbonyl]trimethylene]dipiperidine serving as the base-proliferating agent (D), and 3 g of anthranilic acid (manufactured by Tokyo Chemical Industry Co., Ltd.) serving as the aromatic compound (C) were added to the resultant solution, and the mixture was stirred for 5 hours to provide a negative photosensitive resin composition. In the negative photosensitive resin composition, the content of the aromatic compound (C) with respect to 1 mol of an epoxy group in the epoxy compound (A) was 0.039 mol.

### Application of Negative Photosensitive Resin Composition onto Substrate

Next, the negative photosensitive resin composition was applied onto the substrate by the following method.

First, the resultant negative photosensitive resin composition was applied onto the first surface of the silicon substrate having a hydroxy group by a spin coating method so as to have a thickness of 20 μm. After that, the composition was subjected to heating treatment under a vacuum environment at 60° C. for 3 minutes to form a coating film.

### Production of Photosensitive Structural Body

Next, the coating film on the substrate was exposed with an i-line exposure stepper (manufactured by Canon Inc.) in an exposure amount of 5,000 J/m², and was then subjected to heating treatment at 95° C. for 4 minutes. Further, the coating film was subjected to washing treatment with the mixed solution of methyl isobutyl ketone and xylene, and was then subjected to heating treatment at 140° C. for 4 minutes. Finally, the coating film was heated at 200° C. for 1 hour to be cured. Thus, a photosensitive structural body having a structure in which the cured product of the negative photosensitive resin composition was arranged on the substrate was obtained.

### Production of Inkjet Recording Head

Next, an inkjet recording head was produced by the following method. The flow of the production is illustrated in FIG. 2A to FIG. 2F.

Polymethyl isopropenyl ketone (product name: ODUR-1010, manufactured by Tokyo Ohka Kogyo Co., Ltd.) was applied as a positive resist serving as the ink flow path mold 3 onto the first surface of the silicon substrate 2 having a hydroxy group, the substrate having the energy-generating elements 1 arranged on the first surface, so as to have a thickness of 14 μm, and was subjected to heating treatment at 120° C. for 6 minutes. Next, an ink flow path pattern was exposed on the resultant resist with an exposure device (product name: UX3000, manufactured by Ushio Inc.), and was developed with methyl isobutyl ketone (MIBK) to form the ink flow path mold 3 (FIG. 2A).

Next, the prepared negative photosensitive resin composition was applied as the resin layer 4 serving as the flow path forming member 5 having an ejection orifice onto the ink flow path mold 3 by a spin coating method so as to have a thickness of 20 μm from the ground (substrate 2). After that, heating treatment was performed under a vacuum environment at 60° C. for 3 minutes (FIG. 2B).

Next, the composition was exposed to radiant energy having an exposure amount of 5,000 J/m² with an i-line exposure stepper (manufactured by Canon Inc.) through the photomasks 6 so that portions where ejection orifices were to be formed became the unexposed portions 4A (FIG. 2C). Further, heating treatment was performed at 95° C. for 4 minutes. Next, development was performed with a mixed solution containing xylene and MIBK at 6/4 to remove the unexposed portions 4A, to thereby form the ejection orifices 7 (FIG. 2D).

Further, a mask (not shown) for producing the ink supply orifice 8 was appropriately arranged on the second surface (surface opposite to the first surface) of the substrate, and the surface of the substrate was protected with a rubber film, followed by the production of the ink supply orifice 8 by the anisotropic etching of the silicon substrate (FIG. 2E). After the completion of the anisotropic etching, the rubber film was removed, and the exposure device (product name: UX3000, manufactured by Ushio Inc.) was used again to apply UV light to the entire surface of the substrate. Thus, the positive resist was decomposed. After that, the decomposed positive resist was dissolved and removed with methyl lactate to form the flow path 9 (FIG. 2F). Next, heating treatment was performed at 200° C. for 1 hour for completely curing the negative photosensitive resin composition and an ink-repellent film (not shown), and then electrical connection and an ink-supplying unit were appropriately arranged to provide the inkjet recording head. The ink-repellent film is a thin film formed by applying an ink-repellent agent to the surface of a layer for forming the flow path forming member 5 and curing the agent. The resultant inkjet recording head includes the cured product of the negative photosensitive resin composition as the flow path forming member 5.

### Examples 2 and 3, and Comparative Example 1

Negative photosensitive resin compositions were each prepared in the same manner as in Example 1 except that the addition amount of anthranilic acid serving as the aromatic compound (C) was changed as shown in Table 2.

In addition, photosensitive structural bodies and inkjet recording heads were produced in the same manner as in Example 1 by using the resultant negative photosensitive resin compositions.

### Comparative Example 2

A negative photosensitive resin composition was prepared in the same manner as in Comparative Example 1 except that the addition amount of 4,4′-[bis[[(9-fluorenylmethyl)oxy]carbonyl]trimethylene]dipiperidine serving as the base-proliferating agent (D) was changed as shown in Table 2.

In addition, a photosensitive structural body and an inkjet recording head were produced in the same manner as in Example 1 by using the resultant negative photosensitive resin composition.

### Comparative Example 3

A silicon substrate was subjected to reduced-pressure plasma treatment only with an argon gas. A photosensitive structural body and an inkjet recording head were produced in the same manner as in Example 2 by using the resultant silicon substrate (free of any hydroxy group).

### Measurement and Evaluation

### Evaluation of Photosensitive Structural Body

### Pattern Shape Reproducibility

The area of the formed pattern (pattern at the time of the formation of the ejection orifices in the resin layer 4) of each of the photosensitive structural bodies obtained in the production processes for the inkjet recording heads according to Examples 1 to 3 and Comparative Examples 1 to 3 was measured with VertScan 2.0 (product name) manufactured by Ryoka Systems Inc. Pattern shape reproducibility with respect to the masks was evaluated from the ratio of the resultant pattern area (μm²) to a mask area (μm²) by the following criteria. The results are shown as “Pattern shape reproducibility” in Table 2.

○: The ratio of the pattern area to the mask area is 0.9 or more and less than 1.1.

Δ: The ratio of the pattern area to the mask area is 0.8 or more and less than 0.9, or is 1.1 or more and less than 1.2.

x: The ratio of the pattern area to the mask area is less than 0.8, or is 1.2 or more.

### Adhesiveness

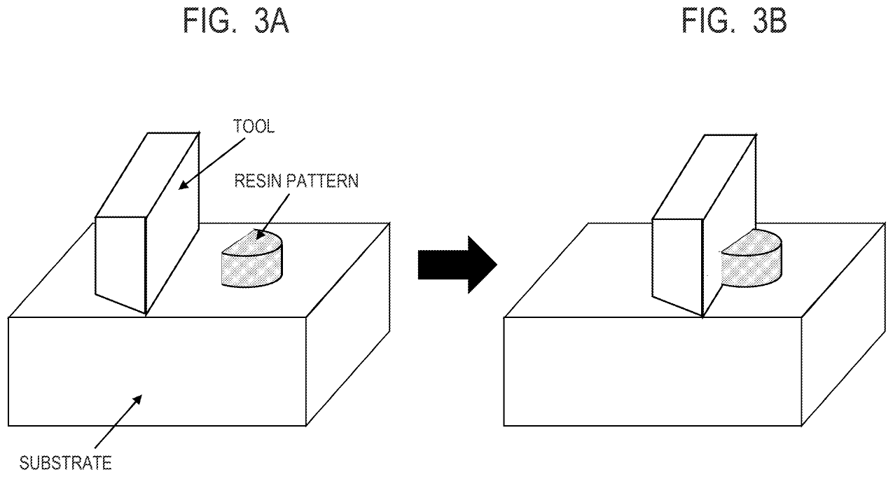

Adhesiveness between the substrate and negative photosensitive resin composition of each of the photosensitive structural bodies produced in Examples 1 to 3 and Comparative Examples 1 to 3 was measured by the following procedure. First, as illustrated in FIG. 3A, the pattern of the negative photosensitive resin composition according to each example or comparative example was formed on the substrate according to each example or comparative example, and the pattern was pressed with a tool (FIG. 3B). The force at which the pattern was pressed with the tool was gradually strengthened, and the adhesiveness was evaluated by measuring the value of the pressing force at the time of the peeling of the pattern from the substrate. The measurement was performed with a strength-measuring device “Bonding Tester PTR-10” (product name) manufactured by Rhesca Co., Ltd. The value of the pressing force at the time of the peeling of the pattern from the substrate is referred to as “shear strength,” and a larger value of the strength means that the adhesiveness between the substrate and the negative photosensitive resin composition is higher. The results are shown as “Shear strength” in Table 2.

### Evaluation of Inkjet Recording Head

### Peeling Resistance

The flow paths of the inkjet recording heads produced in Examples 1 to 3 and Comparative Examples 1 to 3 were filled with an ink formed of blending components shown in Table 1 below, and the recording heads were each left to stand in an oven at 70° C. for 90 days. Carbon black was used as a black pigment.

TABLE 1

| Blending component | Part(s) by mass |
|---|---|
| Diethylene glycol | 10.0 |
| 2-Pyrrolidone | 30.0 |
| 1,2-Hexanediol | 7.0 |
| Acetylenol | 1.0 |
| Black pigment | 3.0 |
| Pure water | 49.0 |

The state of joining between the substrate and the negative photosensitive resin composition in each of the inkjet recording heads after the standing was observed with a metallurgical microscope (product name: MX63L, manufactured by Olympus Corporation), and was evaluated by the following criteria. The results are shown as “Peeling resistance” in Table 2.

○: No peeling occurred between the substrate and the negative photosensitive resin composition.

x: Peeling that had not been observed at the time of the formation of the inkjet head occurred between the substrate and the negative photosensitive resin composition.

TABLE 2

| | | | | | Comparative | Comparative | Comparative |
|---|---|---|---|---|---|---|---|
| | | Example 1 | Example 2 | Example 3 | Example 1 | Example 2 | Example 3 |
| Material of negative | Epoxy compound | 100 | 100 | 100 | 100 | 100 | 100 |
| photosensitive resin | (A) | | | | | | |
| composition/part(s) | Silane coupling | 5 | 5 | 5 | 5 | 5 | 5 |
| by mass | agent | | | | | | |
| | Photobase generator | 5 | 5 | 5 | 5 | 5 | 5 |
| | (B) | | | | | | |
| | Aromatic compound | 3 | 6 | 9 | 0 | 0 | 6 |
| | (C) | | | | | | |
| | Base-proliferating | 10 | 10 | 10 | 10 | 20 | 10 |
| | agent (D) | | | | | | |
| | Solvent | 70 | 70 | 70 | 70 | 70 | 70 |
| Aromatic compound (C) with respect to 1 | | 0.039 | 0.078 | 0.117 | — | — | 0.078 |
| mol of epoxy group/mol | | | | | | | |
| Oxygen gas ratio at time of plasma | | 20 | 20 | 20 | 20 | 20 | 0 |
| treatment of substrate/% | | | | | | | |
| Photosensitive | Pattern shape | ∘ | ∘ | ∘ | ∘ | x | ∘ |
| structural body | reproducibility | | | | | | |
| | Shear strength/g | 21 | 26 | 27 | 12 | 24 | 5 |
| Inkjet recording head | Peeling resistance | ∘ | ∘ | ∘ | x | ∘ | x |

According to the present disclosure, there can be obtained the photosensitive structural body, which can achieve both of adhesiveness between its substrate and negative photosensitive resin composition, and pattern shape reproducibility while suppressing a rise in sensitivity of the negative photosensitive resin composition to light, and the inkjet recording head using the photosensitive structural body.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-176468, filed Oct. 28, 2021, which is hereby incorporated by reference herein in its entirety.

What is claimed is:

1. A photosensitive structural body comprising:
a substrate having a hydroxy group on a first surface thereof; and
a cured product of a negative photosensitive resin composition arranged on the substrate,
wherein the negative photosensitive resin composition contains an epoxy compound (A), a photobase generator (B), and an aromatic compound (C), and the aromatic compound (C) is a compound represented by the following general formula (1): 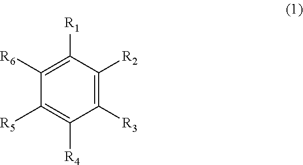
in the general formula (1), four of R₁ to R₆ each independently represent a hydrogen atom or an alkyl group, and remaining two thereof each independently represent a functional group selected from an unsubstituted amino group (—NH₂), a hydroxy group (—OH), and a carboxyl group (—COOH), provided that the two functional groups each selected from an unsubstituted amino group, a hydroxy group, and a carboxyl group are functional groups different from each other.

2. The photosensitive structural body according to claim 1, wherein in the aromatic compound (C), the two functional groups each selected from an unsubstituted amino group, a hydroxy group, and a carboxyl group are an unsubstituted amino group and a carboxyl group.

3. The photosensitive structural body according to claim 1, wherein in the negative photosensitive resin composition, a content of the aromatic compound (C) is 0.065 mol or more and 0.130 mol or less with respect to 1 mol of an epoxy group of the epoxy compound (A).

4. The photosensitive structural body according to claim 2, wherein in the negative photosensitive resin composition, a content of the aromatic compound (C) is 0.065 mol or more and 0.130 mol or less with respect to 1 mol of an epoxy group of the epoxy compound (A).

5. The photosensitive structural body according to claim 1, wherein the negative photosensitive resin composition further contains a base-proliferating agent (D), and a content of the base-proliferating agent (D) is 1 mol or less with respect to 1 mol of the photobase generator (B).

6. The photosensitive structural body according to claim 2, wherein the negative photosensitive resin composition further contains a base-proliferating agent (D), and a content of the base-proliferating agent (D) is 1 mol or less with respect to 1 mol of the photobase generator (B).

7. The photosensitive structural body according to claim 3, wherein the negative photosensitive resin composition further contains a base-proliferating agent (D), and a content of the base-proliferating agent (D) is 1 mol or less with respect to 1 mol of the photobase generator (B).

8. A method of producing a photosensitive structural body comprising:
(i) preparing a substrate having a hydroxy group on a first surface thereof;
(ii) applying, onto the first surface of the substrate having a hydroxy group, a negative photosensitive resin composition containing an epoxy compound (A), a photobase generator (B), and an aromatic compound (C) having a structure represented by the following general formula (1) to form a coating film; and
(iii) curing the coating film,
wherein the aromatic compound (C) is a compound represented by the following general formula (1): 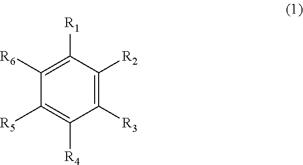
in the general formula (1), four of R₁ to R₆ each independently represent a hydrogen atom or an alkyl group, and remaining two thereof each independently represent a functional group selected from an unsubstituted amino group (—NH₂), a hydroxy group (—OH), and a carboxyl group (—COOH), provided that the two functional groups each selected from an unsubstituted amino group, a hydroxy group, and a carboxyl group are functional groups different from each other.

9. The method of producing a photosensitive structural body according to claim 8, wherein in the aromatic compound (C), the two functional groups each selected from an unsubstituted amino group, a hydroxy group, and a carboxyl group are an unsubstituted amino group and a carboxyl group.

10. The method of producing a photosensitive structural body according to claim 8, wherein in the negative photosensitive resin composition, a content of the aromatic compound (C) is 0.065 mol or more and 0.130 mol or less with respect to 1 mol of an epoxy group of the epoxy compound (A).

11. The method of producing a photosensitive structural body according to claim 9, wherein in the negative photosensitive resin composition, a content of the aromatic compound (C) is 0.065 mol or more and 0.130 mol or less with respect to 1 mol of an epoxy group of the epoxy compound (A).

12. The method of producing a photosensitive structural body according to claim 8, wherein the step (iii) comprises curing the coating film by anionic polymerization.

13. An inkjet recording head comprising:
an ejection orifice configured to eject a liquid;
a substrate having a hydroxy group on a first surface thereof; and
a flow path forming member arranged on the substrate and having a flow path for supplying the liquid to the ejection orifice,
wherein the flow path forming member is a photosensitive structural body including a cured product of a negative photosensitive resin composition, the negative photosensitive resin composition contains an epoxy compound (A), a photobase generator (B), and an aromatic compound (C), and the aromatic compound (C) is a compound represented by the following general formula (1). 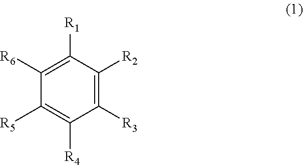
in the general formula (1), four of R₁ to R₆ each independently represent a hydrogen atom or an alkyl group, and remaining two thereof each independently represent a functional group selected from an unsubstituted amino group (—NH₂), a hydroxy group (—OH), and a carboxyl group (—COOH), provided that the two functional groups each selected from an unsubstituted amino group, a hydroxy group, and a carboxyl group are functional groups different from each other.

14. The inkjet recording head according to claim 13, wherein in the aromatic compound (C), the two functional groups each selected from an unsubstituted amino group, a hydroxy group, and a carboxyl group are an unsubstituted amino group and a carboxyl group.

15. The inkjet recording head according to claim 13, wherein in the negative photosensitive resin composition, a content of the aromatic compound (C) is 0.065 mol or more and 0.130 mol or less with respect to 1 mol of an epoxy group of the epoxy compound (A).

16. The inkjet recording head according to claim 14, wherein in the negative photosensitive resin composition, a content of the aromatic compound (C) is 0.065 mol or more and 0.130 mol or less with respect to 1 mol of an epoxy group of the epoxy compound (A).

17. The inkjet recording head according to claim 13, wherein the negative photosensitive resin composition further contains a base-proliferating agent (D), and a content of the base-proliferating agent (D) is 1 mol or less with respect to 1 mol of the photobase generator (B).

18. The inkjet recording head according to claim 14, wherein the negative photosensitive resin composition further contains a base-proliferating agent (D), and a content of the base-proliferating agent (D) is 1 mol or less with respect to 1 mol of the photobase generator (B).

19. The inkjet recording head according to claim 15, wherein the negative photosensitive resin composition further contains a base-proliferating agent (D), and a content of the base-proliferating agent (D) is 1 mol or less with respect to 1 mol of the photobase generator (B).
